(19) United States
(12) Patent Application Publication
(10) Pub. No.: US 2024/0240076 A1
(43) Pub. Date: Jul. 18, 2024

(54) QUANTUM-DOT-CONTAINING FILM, LIGHT-EMITTING ELEMENT, QUANTUM DOT COMPOSITION AND METHOD FOR PRODUCING SAME, AND METHOD FOR PRODUCING QUANTUM-DOT-CONTAINING FILM

(71) Applicant: SHARP KABUSHIKI KAISHA, Sakai City, Osaka (JP)

(72) Inventors: Kazuki GOTO, Sakai City, Osaka (JP); Keisuke KITANO, Sakai City, Osaka (JP); Ryo KITAMURA, Sakai City, Osaka (JP); Masaki YAMAMOTO, Sakai City, Osaka (JP)

(21) Appl. No.: 18/288,284

(22) PCT Filed: May 20, 2021
(86) PCT No.: PCT/JP2021/019165

§ 371 Date: Oct. 25, 2023

(51) Int. Cl. C09K 11/02; B82Y 20/00; B82Y 40/00; C09K 11/88; H10K 50/115; H10K 85/30

(52) U.S. Cl. CPC C09K 11/025; C09K 11/883; H10K 85/381; B82Y 20/00; B82Y 40/00; H10K 50/115

(57) ABSTRACT

An EML includes: quantum dots; inorganic ligands; and alkanolamine. In a unit volume of the EML, a molar ratio of the alkanolamine to the inorganic ligands is in a range of 10 or more and 1000 or less.

### TECHNICAL FIELD

The present disclosure relates to a quantum-dot-containing film, a light-emitting element, a quantum dot composition and a method for producing the quantum dot composition, and a method for producing a quantum-dot-containing film.

### BACKGROUND ART

Typically, organic ligands have been conventionally used as a protectant and a dispersant of quantum dots. However, organic ligands are unstable at high temperature, or in high light flux, or a combination thereof. Furthermore, the organic ligands act as an insulating barrier for the quantum dots made of a semiconductor material. Hence, from viewpoints of, for example, reliability and carrier injection property, quantum dots capped with inorganic ligands have been developed in recent years (for example, see Patent Document 1 and Non-Patent Document 1).

In a development of a light-emitting element including a quantum-dot-containing film containing quantum dots, organic ligands on the surface of the quantum dots are desirably substituted with inorganic ligands (ligand exchange) from viewpoints of, for example, carrier injection and reliability.

### CITATION LIST

### Patent Literature

[Patent Document 1] Japanese Unexamined Patent Application Publication No. 2017-505842

### Non-Patent Literature

Non-Patent Document J. Am. Chem. Soc. 2011, 133, 10612-10620

### SUMMARY OF INVENTION

### Technical Problems

A quantum dot composition, which contains inorganic ligands exchanged with by a conventional technique, quantum dots, and a solvent, cannot form a quantum-dot-containing film that develops little unevenness and exhibits excellent emission characteristics. In particular, when organic ligands are exchanged for inorganic ligands in a state of solution using a conventional technique, a quantum yield of the quantum dot composition inevitably decreases. For example, Non-Patent Document 1 discloses that when organic ligands on the surface of CdSe nanocrystals is exchanged for S²⁻ inorganic ligands, the photoluminescence quantum yield decreases from 13% to 2%. Furthermore, Non-Patent Document 1 discloses that when organic ligands on the surface of nanocrystals having a CdSe—ZnS core-shell structure are exchanged for S²⁻ inorganic ligands, the photoluminescence quantum yield decreases from 65% to 25%. Hence, when the quantum-dot-containing film is, for example, a light-emitting layer of a light-emitting element, it is impossible to produce a light-emitting element having excellent emission characteristics.

An aspect of the present disclosure is devised in view of the above problems, and set out to provide a quantum dot composition and a method for producing the quantum dot composition, and a method for producing a quantum-dot-containing film to be suitably used for producing the quantum-dot-containing film and a light-emitting element that develops little unevenness and exhibits excellent emission characteristics, and the quantum-dot-containing film.

### Solution to Problems

In order to solve the above problems, a quantum-dot-containing film according to an aspect of the present disclosure includes: quantum dots; inorganic ligands; and alkanolamine. In a unit volume of the quantum-dot-containing film, a molar ratio of the alkanolamine to the inorganic ligands is in a range of 10 or more and 1000 or less.

In order to solve the above problems, a light-emitting element according to an aspect of the present disclosure includes: a first electrode; a second electrode; and a light-emitting layer provided between the first electrode and the second electrode. The light-emitting layer is the quantum-dot-containing film according to an aspect of the present disclosure.

In order to solve the above problems, a quantum dot composition according to an aspect of the present disclosure includes: quantum dots; inorganic ligands; alkanolamine; and a first organic solvent. In a unit volume of the quantum dot composition, a molar ratio of the alkanolamine to the inorganic ligands is in a range of 10 or more and 1000 or less.

In order to solve the above problems, a method for producing the quantum dot composition according to an aspect of the present disclosure includes: a ligand exchange step of carrying out ligand exchange by mixing together (i) a first quantum dot composition containing the quantum dots, organic ligands, and a second organic solvent, (ii) an inorganic ligand solution containing the inorganic ligands and a third organic solvent, and (iii) the alkanolamine; and a mixing step of (i) recovering a second quantum dot composition obtained at the ligand exchange step and containing the quantum dots, the inorganic ligands, the third organic solvent, and the alkanolamine, (ii) rinsing the second quantum dot composition with a rinsing solution, (iii) recovering a third quantum dot composition containing the quantum dots, the inorganic ligands, and the alkanolamine, and (iv) mixing the third quantum dot composition with the first organic solvent.

In order to solve the above problems, a method for producing a quantum-dot-containing film according to an aspect of the present disclosure is to deposit the quantum-dot-containing film by coating with the quantum dot composition according to an aspect of the present disclosure.

### Advantageous Effects of Invention

An aspect of the present disclosure can provide a quantum dot composition and a method for producing the quantum dot composition, and a method for producing a quantum-dot-containing film to be suitably used for producing the quantum-dot-containing film and a light-emitting element that develops little unevenness and exhibits excellent emission characteristics, and the quantum-dot-containing film.

### BRIEF DESCRIPTION OF DRAWINGS

FIG. 1 is a cross-sectional view of a schematic configuration of a light-emitting element according to a first embodiment.

FIG. 2 is a diagram illustrating an example of a quantum dot composition according to the first embodiment.

FIG. 3 is a flowchart showing an exemplary method for producing the light-emitting element according to the first embodiment.

FIG. 4 is a flowchart showing an exemplary method for producing the quantum dot composition according to the first embodiment.

FIG. 5 is a diagram schematically illustrating a part of the method for producing the quantum dot composition illustrated in FIG. 4.

FIG. 6 is a diagram schematically illustrating another part of the method for producing the quantum dot composition illustrated in FIG. 4.

FIG. 7 is a PL photomicrograph of a surface of a quantum-dot-containing film obtained in Example 1.

FIG. 8 is a Nomarski differential interference contrast photomicrograph of the surface of the quantum-dot-containing film obtained in Example 1.

FIG. 9 is a PL photomicrograph of a surface of a quantum-dot-containing film obtained in Comparative Example 1.

FIG. 10 is a Nomarski differential interference contrast photomicrograph of the surface of the quantum-dot-containing film obtained in Comparative Example 1.

FIG. 11 is a graph showing a relationship between a current density and an external quantum efficiency in the light-emitting element obtained in each of Example 1 and Comparative Example 1.

FIG. 12 is a graph showing a density of a current flowing with respect to a voltage applied to the light-emitting element obtained in each of Example 1 and Comparative Example 1.

FIG. 13 is a graph showing a relationship between: a molar ratio of ethanolamine to S²⁻ in the light-emitting element obtained in each of Examples 2 to 4 and Comparative Examples 2 to 4; and a PLQY of a quantum dot composition after substitution of ligands in each of Examples 2 to 4 and Comparative Examples 2 to 4.

### DESCRIPTION OF EMBODIMENTS

### First Embodiment

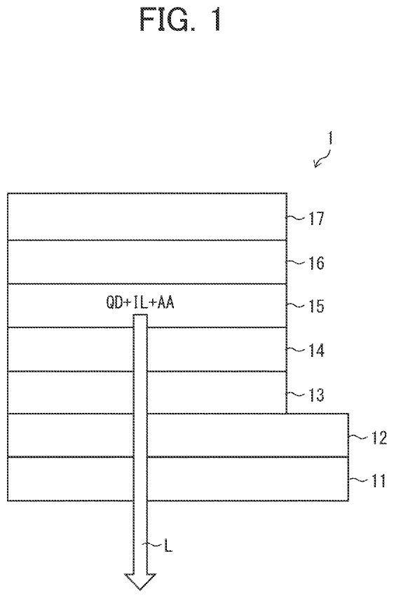

An embodiment of the present disclosure will be described below, with reference to FIGS. 1 to 13. In the description below, the statement “A to B” as to two numbers A and B means “A or more and B or less” unless otherwise specified.

This embodiment exemplifies a case where a quantum-dot-containing film according to the present disclosure is a light-emitting layer of a light-emitting element.

### Light-Emitting Element

The light-emitting element according to this embodiment is an electroluminescent element that emits light upon application of a voltage. The light-emitting element is a quantum-dot light-emitting diode (QLED) containing quantum dots as a light-emitting material. The quantum dots are contained in a light-emitting layer (hereinafter referred to as “EML”) provided between an anode and a cathode. The quantum dots emit light by combination of holes supplied from the anode and electrons (free electrons) supplied from the cathode.

FIG. 1 is a cross-sectional view of a schematic configuration of a light-emitting element 1 according to this embodiment.

As illustrated in FIG. 1, the light-emitting element 1 includes: an anode 12 (a first electrode); a cathode 17 (a second electrode); and a functional layer provided between the anode 12 and the cathode 17, and including at least an EML 15. Note that, in this embodiment, a layer between the anode 12 and the cathode 17 is collectively referred to as a functional layer.

The functional layer may be either a single layer including the EML 15 alone, or a multilayer including a functional layer other than the EML 15. Examples of the functional layer other than the EML 15 include: a hole injection layer (hereinafter referred to as “HIL”); a hole transport layer (hereinafter referred to as “HTL”); and an electron transport layer (hereinafter referred to as “ETL”).

Note that, in the present disclosure, a direction from the anode 12 toward the cathode 17 in FIG. 1 is referred to as an upward direction, and a direction opposite the upward direction is referred to as a downward direction. Furthermore, in the present disclosure, a horizontal direction is a direction perpendicular to a vertical direction (a direction along a principal plane of each of the units included in the light-emitting element 1). The vertical direction can also be interpreted as a direction of the normal to each of the units.

Each of the layers from the anode 12 to the cathode 17 is typically supported by a substrate serving as a support. Hence, the light-emitting element 1 may include a substrate as the support.

The light-emitting element 1 illustrated in FIG. 1 includes, for example: a substrate 11; the anode 12; an HIL 13; an HTL 14; an EML 15; an ETL 16; and the cathode 17, all of which are stacked on top of another in the stated order from below upward.

Hereinafter, each of the above layers will be described in more detail.

As described above, the substrate 11 is a support for forming each of the layers from the anode 12 to the cathode 17.

Note that the light-emitting element 1 may be used as a light source of, for example, such an electronic device as a display device. If the light-emitting element 1 is, for example, a portion of a display device, the substrate 11 to be used is a substrate of the display device. Hence, the light-emitting element 1 may be referred to as the light-emitting element 1 with the substrate 11 included therein, or may be referred to as the light-emitting element 1 without the substrate 11.

As can be seen, the light-emitting element 1 itself may include the substrate 11. The substrate 11 included in the light-emitting element 1 may be a substrate of such an electronic device as a display device including the light-emitting element 1. When the light-emitting element 1 is, for example, a portion of a display device, the substrate 11 to be used may be, for example, an array substrate on which a plurality of thin-film transistors are formed. In this case, the anode 12 serving as a first electrode provided on the substrate 11 may be electrically connected to a thin-film transistor (TFT) on the array substrate.

As can be seen, if the light-emitting element 1 is, for example, a portion of a display device, the light-emitting element 1 is provided to the substrate 11 for each of the pixels to serve as a light source. Specifically, a red pixel (an R pixel) is provided with a light-emitting element (a red light-emitting element) that serves as a red light source and emits a red light. A green pixel (a G pixel) is provided with a light-emitting element (a green light-emitting element) that serves as a green light source and emits a green light. A blue pixel (a B pixel) is provided with a light-emitting element (a blue light-emitting element) that serves as a blue light source and emits a blue light. Hence, the substrate 11 may have a bank formed to serve as a pixel separating film to partition the pixels from one another, so that the R pixel, the G pixel, and the B pixel are provided with respective light-emitting elements.

In a bottom-emission (BE) light-emitting element having a BE structure, light emitted from the EML 15 is released downwards (i.e., toward the substrate 11). In a top-emission (TE) light-emitting element having a TE structure, light emitted from the EML 15 is released upwards (i.e., across from the substrate 11). In a double-sided light-emitting element, light emitted from the EML 15 is released downwards and upwards.

If the light-emitting element 1 is a BE light-emitting element or a double-sided light-emitting element, the substrate 11 is made of a light-transparent substrate relatively highly transparent to light. The substrate 11 is, for example, a glass substrate.

Whereas, if the light-emitting element 1 is a TE light-emitting element, the substrate 11 may be made of a substrate not relatively transparent to light, such as, for example, a plastic substrate. Alternatively, the substrate 11 may be a light-reflective substrate reflective to light. Note that, as to the TE structure, the light-emitting surface does not have many obstacles to light, such as TFTs. Hence, the TE structure can have a large aperture ratio, and further increase in external quantum efficiency.

Of the anode 12 and the cathode 17, the electrode provided toward a light-releasing face needs to be transparent to light. Note that the electrode across from the light-releasing face may be either transparent to light or nontransparent to light.

For example, if the light-emitting element 1 is a BE light-emitting element, the upper electrode is a light-reflective electrode and the lower electrode is a light-transparent electrode. If the light-emitting element 1 is a TE light-emitting element, the upper electrode is a light-transparent electrode and the lower electrode is a light-reflective electrode. Note that the light-reflective electrode may be a multilayer stack including a layer made of a light-transparent material and a layer made of a light-reflective material.

FIG. 1 shows, as an example, a case where the light-emitting element 1 is a BE light-emitting element in which the anode 12 is an electrode provided below (a lower electrode), the cathode 17 is an electrode provided above (an upper electrode), and light L emitted from the EML 15 is released downwards. Hence, the anode 12 is a light-transparent electrode, so that the light L emitted from the EML 15 can be transmitted through the anode 12. Furthermore, the cathode 17 is a light-reflective electrode, so that the light L emitted from the EML 15 can be reflected on the cathode 17. Note that the lower electrode has an edge covered with a not-shown edge cover. As can be seen, if the light-emitting element 1 is, for example, a portion of a display device, the edge cover may also serve as the bank (the pixel separating film) to partition the pixels from one another.

The anode 12 is an electrode that receives a voltage and supplies the holes to the EML 15. The anode 12 is made of, for example, a material having a relatively large work function. Examples of the material include: tin-doped indium oxide (ITO); zinc-doped indium oxide (IZO); aluminum-doped zinc oxide (AZO); gallium-doped zinc oxide (GZO); and antimony-doped tin oxide (ATO). These materials may be used alone or in combination of two or more as appropriate.

The cathode 17 is an electrode that receives a voltage and supplies the electrons to the EML 15. The cathode 17 is made of, for example, a material having a relatively small work function. Examples of the material include: aluminum (Al); silver (Ag); barium (Ba); ytterbium (Yb); calcium (Ca); a lithium (Li)—Al alloy, a magnesium (Mg)—Al alloy, a Mg—Ag alloy, a Mg-indium (In) alloy, and an Al-aluminum oxide (Al₂O₃) alloy.

The HIL 13 transports the holes, supplied from the anode 12, to the HTL 14. The HIL 13 is made of a hole transporting material. The hole transporting material may be either an organic material or an inorganic material. If the hole transporting material is an organic material, the organic material may be, for example, a conductive polymer material. The polymer material may be, for example, a composite (PEDOT:PSS) of poly(3,4-ethylenedioxythiophene) (PEDOT) and polystyrene sulphonate (PSS), as will be described later in Example 1.

The HTL 14 transports the holes, supplied from the HIL 13, to the EML 15. The HTL 14 is made of a hole transporting material. The hole transporting material may be either an organic material or an inorganic material. If the hole transporting material is an organic material, the organic material may be, for example, a conductive polymer material. Examples of the polymer material may include: poly[(9,9-dioctylfluorenyl-2,7-diyl)-co-(4,4′-(N-(4-sec-butylphenyl)diphenylamine))] (TFB); and N,N′-bis(4-butylphenyl)-N,N′-bis(phenyl)-benzidine (poly-TPD). These polymer materials may be used alone, or in combination of two or more as appropriate. In Example 1 to be described later, as an example, poly-TPD is used for the HTL 14. Note that if the HTL 14 alone can sufficiently supply the holes to the EML 15, the HIL 13 may be omitted.

Furthermore, the HTL 14 may have a surface modified by, for example, a UV-O₃ treatment using O₃ (ozone) produced with UV (an ultraviolet ray). In Example 1 to be described later, for example, a poly-TPD film is deposited. After that, the surface of the poly-TPD is modified by a UV-O₃ treatment. Such features can facilitate deposition of the EML 15 whose ligands are substituted with inorganic ligands.

The ETL 16 transports the electrons, supplied from the cathode 17, to the EML 15. The ETL 16 is made of an electron transporting material. The electron transporting material may be either an organic material or an inorganic material.

If the electron transporting material is an inorganic material, the inorganic material is preferably nanoparticles made of a metal oxide containing at least one element selected from the group consisting of: zinc (Zn); magnesium (Mg); titanium (Ti); silicon (Si); tin (Sn); tungsten (W); tantalum (Ta); barium (Ba); zirconium (Zr); aluminum (Al); yttrium (Y); and hafnium (Hf). The metal oxide preferably includes zinc oxide (ZnO) and zinc oxide magnesium (ZnMgO) in view of, for example, electron mobility. These metal oxides may be used alone, or in combination of two or more as appropriate. Among the above inorganic materials, the ETL 16 preferably contains ZnMgO. Such a feature can provide the light-emitting element 1 with high electron mobility and excellent emission characteristics.

Furthermore, if the electron transporting material is an organic material, the organic material preferably contains at least one compound selected from the group consisting of, for example: 1,3,5-tris(1-phenyl-1H-benzimidazole-2-yl)benzene (TPBi); 3-(biphenyl-4-yl)-5-(4-tert-butylphenyl)-4-phenyl-4H-1,2,4-triazole (TAZ); bathophenanthroline (Bphen); and tris (2,4,6-trimethyl-3-(pyridin-3-yl) phenyl)borane (3 TPYMB). These organic materials may be used alone, or in combination of two or more as appropriate.

The EML 15 is a quantum-dot light-emitting layer including a quantum-dot-containing film containing a plurality of quantum dots serving as a light-emitting material. Hereinafter, the quantum dot is referred to as “QD”. Furthermore, the quantum-dot-containing film is referred to as a “QD-containing film”, and the quantum-dot light-emitting layer is referred to as a “QD light-emitting layer”.

In FIG. 1, the sign “IL” denotes inorganic ligands, and the sign “AA” denotes alkanolamine. The EML 15 according to this embodiment, as illustrated in FIG. 1, contains: the QDs; the inorganic ligands (IL); and alkanolamine (AA) serving as a surfactant.

The QDs are inorganic nanoparticles having a particle size of several nanometers to several tens of namometers. The QDs are also referred to as semiconductor nanoparticles because a composition of the QDs is derived from a semiconductor material. Furthermore, as described above, the QDs are also referred to as nanocrystals because a structure of the QDs is a specific crystal structure. Moreover, the QDs are also referred to as fluorescent nanoparticles or QD phosphor particles because the QDs emit fluorescence and have a size by nano-order. Hence, the QD light-emitting layer is also referred to as a QD phosphor layer.

The QDs emit the light L upon recombination of the holes supplied from the anode 12 and the electrons (the free electrons) supplied from the cathode 17. That is, the EML 15 emits light by EL (electroluminescence).

The QDs may contain a semiconductor material made of at least one element selected from the group consisting of, for example: Cd (cadmium); S (sulfur); Te (tellurium); Se (selenium); Zn (zinc); In (indium); N (nitrogen); P (phosphorus); As (arsenic); Sb (antimony); Al (aluminum); Ga (gallium); Pb (lead); Si (silicon); Ge (germanium); and Mg (magnesium).

Each of the QDs may be a core QD, a core-shell QD, or a core-multishell QD. Furthermore, the QD may be a binary-core QD, a tertiary-core QD, or a quaternary-core QD. Note that the QDs may contain doped nanoparticles, or may have a composition-graded structure.

Examples of the QDs include QDs having a core made of, for example: CdSe (cadmium selenide); InP (indium phosphide); ZnSe (zinc selenide); and copper indium gallium selenide (CIGS, CuInₓGa₍₁₋ₓ₎Se₂). Furthermore, the QDs may have a core-shell structure such as: CdSe—CdS (cadmium sulfide); InP—ZnS (zinc sulfide); ZnSe—ZnS, or CIGS-ZnS. An emission wavelength of the QDs can be changed in various manners depending on, for example, the size and the composition of the particles.

The inorganic ligands shall not be limited to particular ligands, and may include various known inorganic ligands not containing carbon components. The inorganic ligands preferably contain at least one kind of inorganic ligands selected from the group consisting of, for example, monoatomic anions or polyatomic anions containing a group 16 element. The at least one kind of inorganic ligands preferably contains: at least one kind of inorganic ligands selected from the group consisting of monoatomic anions or polyatomic anions containing a sulfur element; and monoatomic anions containing a group 16 element. Furthermore, the monoatomic anions containing a group 16 element more preferably contain at least one selected from the group consisting of S²⁻, Se²⁻, and Te²⁻, and still more preferably contain S²⁻ (sulfide ions), which is monoatomic anions containing a sulfur element. Hence, the above inorganic ligands preferably contain S²⁻.

Note that examples of the monoatomic anions containing a group 16 element include S²⁻, Se²⁻, and Te²⁻. Among monoatomic anions containing a group 16 element, preferably used are at least one kind of anions selected from the group consisting of S²⁻, Se²⁻, and Te²⁻. Furthermore, examples of the polyatomic anions containing a group 16 element include HS⁻, SnS₄⁴⁻, SnSe₄⁴⁻, SnTe₄⁴⁻, Sn₂S₆⁴⁻, Sn₂Se₆⁴⁻, and Sn₂Te₆⁴⁻. Examples of the monoatomic anions or the polyatomic anions containing a sulfur element include S²⁻, HS⁻, SnSe₄⁴⁻, and Sn₂S₆⁴⁻.

Note that inorganic salt (a ligand material), serving as a supply source of the anions and formed of the anions and the cations combined together, shall not be limited to a particular inorganic salt. The inorganic salt is selected to contain a combination of any kinds of anions and cations. Note that, in this embodiment, the inorganic salt serving as a supply source of S²⁻ is, for example, Na₂S (sodium sulfide; specifically, Na₂S·9H₂O (disodium sulfide decahydrate) or (NH₄)₂S (ammonium sulfide).

Note that the inorganic ligands shall not be limited to the examples described above, and may be inorganic ligands such as, for example, halide ions such as F⁻ or Cl⁻ other than the inorganic ligands other than the above examples.

Furthermore, as the above alkanolamine, various known alkanolamines may be used. The polarity means that, if a substance exhibits a large difference in charge density in the molecules, the substance shows a large polarity. Hence, when alkane skeletons increase, carbon chains having no difference in charge density between the bonds affect more significantly than an amino group and a hydroxy group exhibiting a difference in charge density by hydrogen bonding. In this case, the polarity (relative permittivity) of the alkanolamine is lower as the carbon chains are longer, and the alkanolamine is less soluble in a polar organic solvent (a first organic solvent). As a result, a sufficient amount of alkanolamine to be coordinated with QDs might not be available in substitution with inorganic ligands. Hence, the above alkanolamine preferably contain in particular an alkane skeleton having 1 to 5 carbon atoms.

Furthermore, in a unit volume of the EML 15 serving as a quantum-dot-containing film, a molar ratio (a mass ratio) of the alkanolamine to the inorganic ligands is preferably in a range of 10 or more and 1000 or less.

As will be described later, the EML 15 is formed of a quantum dot composition containing: the QDs, the inorganic ligands; alkanolamine; and a polar organic solvent (the first organic solvent). The quantum dot composition is applied to an underlayer (the HTL 14 in the example of FIG. 1), and the solvent is removed from the quantum dot composition. Hence, the quantum dot composition forms the EML 15. Hereinafter, the quantum dot composition is referred to as “QD composition”. Note that the QD composition will be described later.

In the light-emitting element 1, a forward voltage is applied between the anode 12 and the cathode 17. In other words, the anode 12 is set to have a higher potential than the cathode 17. Hence, (i) the electrons can be supplied from the cathode 17 to the EML 15, and (ii) the holes can be supplied from the anode 12 to the EML 15. As a result, the EML 15 can generate the light L while the holes and the electrons recombine together. The application of the voltage may be controlled by a not-shown thin-film transistor (TFT). As an example, a TFT layer including a plurality of TFTs may be formed in the substrate 11.

Note that the light-emitting element 1 may include, as a functional layer, a hole blocking layer (HBL) to reduce transportation of the holes. Such a feature makes it possible to adjust balance of carriers (i.e., the holes and the electrons) to be supplied to the EML 15.

Furthermore, the light-emitting element 1 may include, as a functional layer, an electron blocking layer (EBL) to reduce transportation of the electrons. Such a feature makes it possible to adjust balance of carriers (i.e., the holes and the electrons) to be supplied to the EML 15.

Moreover, the light-emitting element 1 may be sealed after the layers up to the cathode 17 have been deposited. The sealing member may be, for example, glass or plastic. The sealing member is, for example, concave so that a multilayer stack from the substrate 11 to the cathode 17 can be sealed. For example, a sealing adhesive (for example, an epoxy-based adhesive) is applied between the sealing member and the substrate 11. After that, the sealing member and the substrate 11 are sealed in a nitrogen (N₂) atmosphere. Hence, the light-emitting element 1 is produced.

Furthermore, the light-emitting element 1 may include: the cathode 17; the ETL 16; the EML 15; the HTL 14; the HIL 13; and the anode 12, all of which are stacked on top of another in the stated order above the substrate 11. Moreover, if the light-emitting element 1 includes the ETL 16 as described above, the light-emitting element 1 may include an electron injection layer (EIL) between the ETL 16 and the cathode 17.

Note that the thickness of each layer in the light-emitting element 1 is not limited to a particular thickness, and can be set in the same manner as conventionally set.

### QD Composition

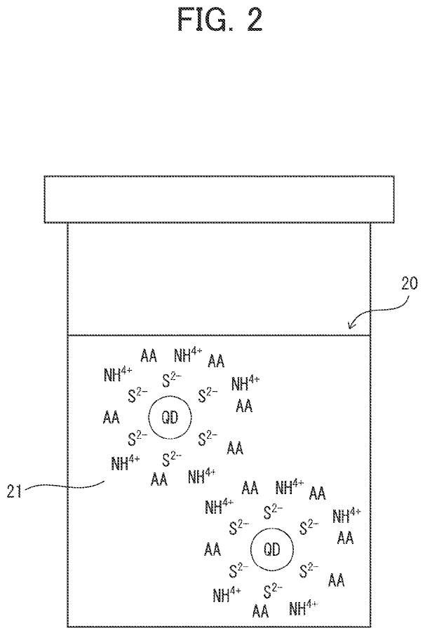

Next, the QD composition will be described. FIG. 2 is a diagram illustrating an example of a QD composition 20 according to this embodiment. Note that FIG. 2 shows, as an example, a case where the inorganic ligands contain S²⁻, and the inorganic salt serving as a supply source of the S²⁻ is (NH₄)₂S (ammonium sulfide). Furthermore, in FIG. 2, the sign “AA” denotes alkanolamine.

As illustrated in FIG. 2, the QD composition 20 according to this embodiment is referred to as a colloidal solution containing the QDs, the inorganic ligands, the alkanolamine (AA), and a solvent 21 (a first organic solvent) that is a polar organic solvent.

The inorganic ligands are found in the QD composition 20 as anions and cations. The anions are at least partially coordinated with the surface of the QDs. Note that FIG. 2 shows, as an example, a case where, when the inorganic salt is (NH₄)₂S, the anions are S²⁻, the cations are H⁴⁺ (ammonium ions), and S²⁻ is at least partially coordinated with the surface of the QDs.

As illustrated in FIG. 2, in the solvent 21, the QDs with which the anions are coordinated as the inorganic ligands are colloidally dispersed. As described above, the inorganic ligands are coordinated with the surface of the QDs, such that the QDs are less likely to agglomerate together. Hence, target optical properties are easily expressed.

Furthermore, in a unit volume of the QD composition 20 according to this embodiment, a molar ratio (a mass ratio) of the alkanolamine to the inorganic ligands is preferably in a range of 10 or more and 1000 or less. Thus, the QD composition 20 can have a photoluminescence quantum yield (PLQY) of more than 50% in a state of solution.

For synthesis of the QDs in the solution, organic ligands to be used dissolve (disperse) in a nonpolar organic solvent. With the surface of the QDs synthesized by the wet process (solution processing), the organic ligands are coordinated as ligands. As can be seen, the ligands coordinated with the surface of the QDs (surface modification) control the particle size of the QDs. Furthermore, the ligands also serve as a dispersant to improve dispersibility of QDs in the QD composition. The ligands are also used to improve the surface stability and the preservation stability of QDs. The ligands coordinated with the surface of the QDs can reduce agglomeration of the QDs themselves. Commercially available (i.e., commercially supplied) liquid QD compositions commonly include organic ligands that dissolve (disperse) in a nonpolar organic solvent.

When the organic ligands, coordinated with the synthesized or commercially obtained QDs, are substituted with inorganic ligands (ligand exchange), if the ligand exchange is carried out in a state of solution by a conventional technique, a PLQY of the QD composition inevitably decreases in the state of solution after the ligand exchange.

However, in this embodiment, as described later, an appropriate amount of alkanolamine such as, in particular, ethanolamine is added as a surfactant together with a ligand material (e.g., Na₂S) when the ligand exchange to the inorganic ligands is carried out in the state of solution. Thus, the ligand exchange can be carried out while the PLQY of the QD composition is maintained in the state of solution. Hence, highly efficient QLEDs can be produced, using the inorganic ligands as ligands.

Although the reason for this advantageous effect is not clear, it is probably because the alkanolamine is coordinated with an insufficiently protected portion of the QD surface (i.e., a portion in which neither substitution with, nor coordination of, the inorganic ligands (S²⁻, in the example of FIG. 2) is carried out), thereby preventing deactivation of the QDs. Furthermore, it is probably because the alkanolamine assists dispersion of the QDs in the solvent 21 and prevents aggregation and deterioration of the QDs.

The solvent 21 is an organic solvent as described above. As the solvent 21, a polar organic solvent is used so that the QDs, with which the inorganic ligands are coordinated, can be dispersed in the solvent. The solvent 21 is preferably at least one organic solvent selected from the group consisting of polar organic solvents having a relative permittivity (εᵣ value) of 24.6 or more and 111.0 or less measured approximately at 20° C. to 25° C.

Examples of the solvent 21 include: ethanol (εᵣ=24.6); methanol (εᵣ=32.7); N,N-dimethylformamide (DMF) (εᵣ=36.7); acetonitrile (εᵣ=37.5); ethylene glycol (εᵣ=37.7); dimethyl sulfoxide (εᵣ=46.7); and formamide (FA) (εᵣ=111.0).

Note that typically disclosed permittivity and relative permittivity are values measured approximately at 20° C. to 25° C. Such typically disclosed permittivity and relative permittivity can be directly employed as a permittivity and a relative permittivity. Note that any given technique and apparatus may be used to measure the permittivity and the relative permittivity. As an example, a liquid permittivity meter can be used.

Thus, as the solvent 21, an organic solvent having a relative permittivity of 24.6≤εᵣ≤111.0 is used, so that QDs with which the inorganic ligands are coordinated can be uniformly dispersed in the solvent 21.

Note that the concentrations of QDs, inorganic ligands, and alkanolamine in the QD composition 20 may be set in the same manner as conventionally set. The concentrations shall not be limited to particular concentrations as long as the QD composition has an applicable concentration or viscosity. The optimum concentration and viscosity vary, depending on deposition techniques.

### Methods for Producing Light-Emitting Element and QD-Containing Film

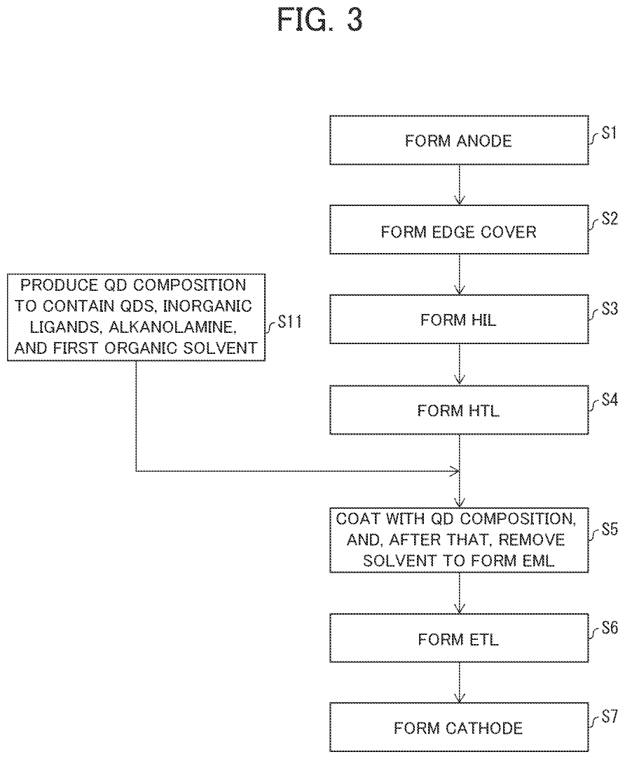

Next, a method for producing the QD-containing film will be described, citing as an example a method for producing a light-emitting layer formed in the process of producing the light-emitting element 1. FIG. 3 is a flowchart showing an exemplary method for producing the light-emitting element 1 according to this embodiment. Note that FIG. 3 shows, as an example, a method for producing the light-emitting element 1 illustrated in FIG. 1.

As illustrated in FIG. 3, in the method for producing the light-emitting element 1 according to this embodiment, first, as an example, the anode 12 is formed on the substrate 11 (Step S1). Next, a not-shown edge cover is formed to cover an edge of the anode 12 (Step S2). Next, the HIL 13 is formed (Step S3). Next, the HTL 14 is formed (Step S4). Separately, the QD composition 20 is produced (prepared) to contain QDs, inorganic ligands, alkanolamine, and the solvent 21 (the first organic solvent) (Step S11). Then, after Step S4 and Step S11, the EML 15 serving as a QD-containing film is formed by liquid-phase film-deposition (Step S5). Specifically, the HTL 14 is coated with the QD composition 20. After that, the solvent 21 is removed from the QD composition 20, so that the QD composition 20 dries. Hence, the EML 15 is formed (deposited). Next, the ETL 16 is formed (Step S6). Next, the cathode 17 is formed (Step S7).

At Step S1 and Step S7, the anode 12 and the cathode 17 are deposited by such a technique as: physical vapor deposition (PVD) including sputtering and vacuum evaporation; spin coating; or inkjet printing.

At Step S2, the edge cover is a layer made of an insulating material deposited by, for example: the PVD such as sputtering or vacuum evaporation; spin coating; or inkjet printing. The layer is patterned by such a technique as photolithography, so that the edge cover can be formed to have a desired shape.

Furthermore, at Step S6, if the ETL 16 is made of an inorganic material, the ETL 16 is ideally deposited by, for example: the PVD such as sputtering, or vacuum evaporation; spin coating; or inkjet printing. Moreover, at Step S6, if the ETL 16 is made of an organic material, the ETL 16 is ideally deposited by, for example: vacuum evaporation; spin coating; or inkjet printing.

The HIL 13 and the HTL 14 are deposited respectively at Step S3 and Step S4 by the same techniques as the technique used for deposition of the ETL 16. That is, if the HIL 13 or the HTL 14 is an inorganic film made of an inorganic material, the inorganic film is ideally deposited by, for example: the PVD such as sputtering, or vacuum evaporation; spin coating; or inkjet printing. Furthermore, if the HIL 13 or the HTL 14 is an organic film made of an organic material, the organic film is ideally deposited by, for example: vacuum evaporation; spin coating; or inkjet printing.

Moreover, at Step S2 and Step S3, the EML 15 is formed of the QD composition 20 as described above. The QD composition is applied to, for example, the HTL 14 serving as an underlayer of the EML 15. The solvent is removed from the QD composition 20, so that the EML 15 is formed (deposited). Note that the EML 15 is formed by such techniques as spin coating, inkjet printing, and photolithography.

As described above, the QD composition 20 used at Step S5 is prepared in advance prior to Step S5. Hence, as shown in FIG. 3, the method for producing the light-emitting element 1 further and separately includes a step (Step S11) of producing the QD composition 20 prior to Step S5.

### Method for Producing QD Composition

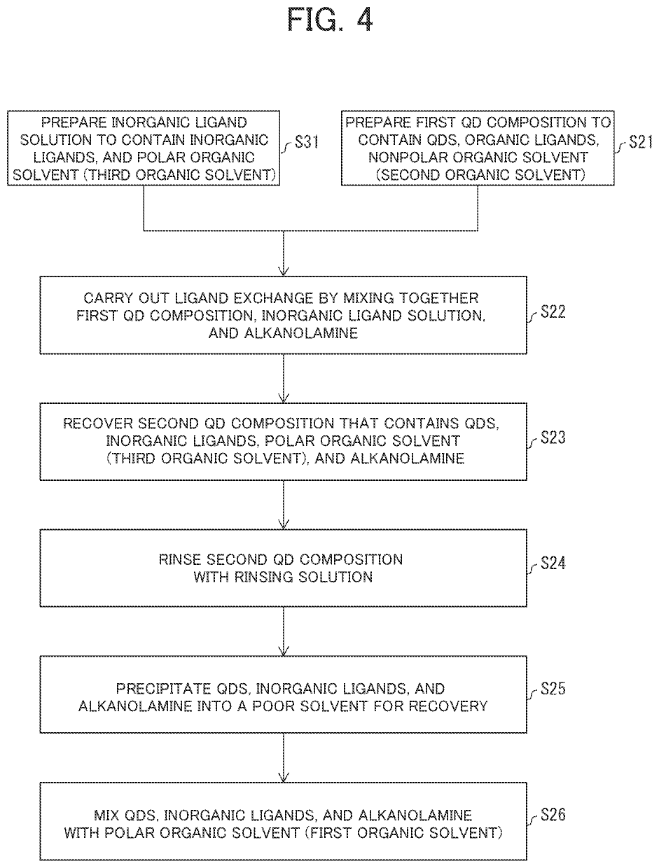

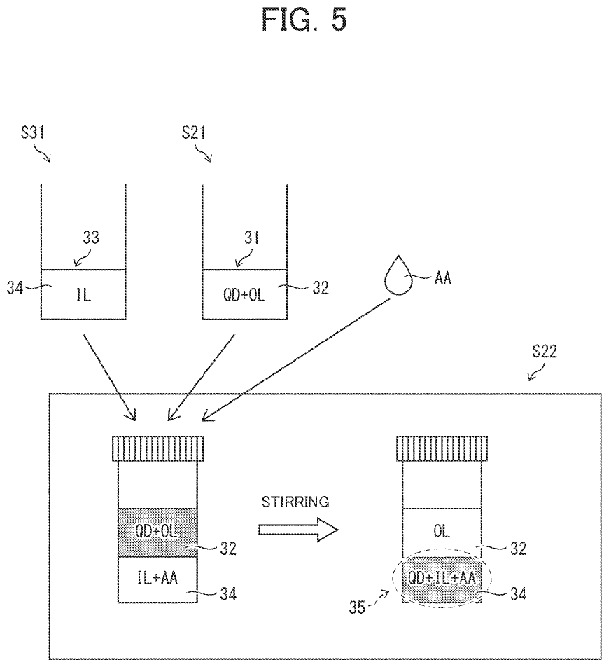

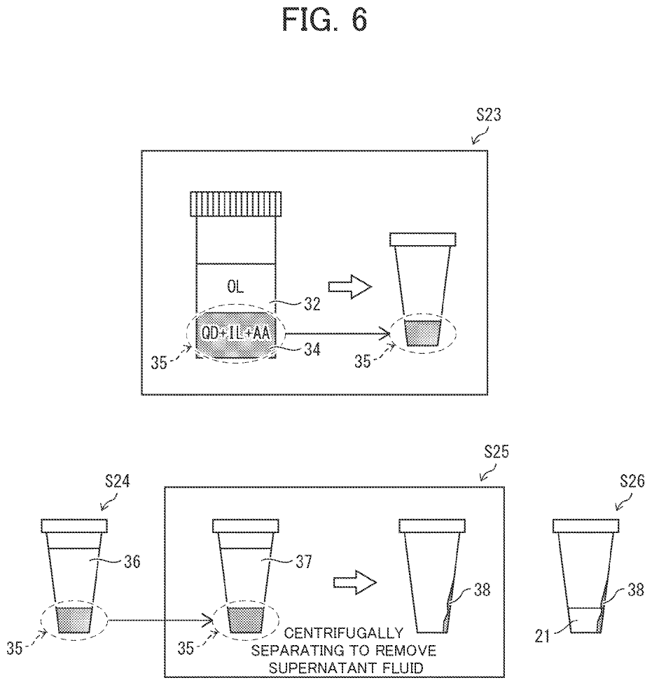

Next, as a method for producing the QD composition 20, above Step S11 will be described as an example. FIG. 4 is a flowchart showing an exemplary method for producing the QD composition 20 according to this embodiment. The method is carried out at above Step S11. Furthermore, each of FIG. 5 and FIG. 6 is a diagram schematically illustrating a part of the method for producing the quantum dot composition 20 illustrated in FIG. 4. Note that FIG. 5 illustrates Step S31, Step S21, and Step S22 shown in FIG. 4. Furthermore, FIG. 6 illustrates Step S23 to Step S26 shown in FIG. 4.

Hereinafter, organic ligands to be substituted for, and coordinated with the QDs synthesized or commercially obtained as described above (i.e., organic ligands dissolved (dispersed) in a nonpolar organic solvent), will be referred to as “original ligands”. In FIGS. 5 and 6, the sign “OL” denotes the original ligands (organic ligands). Furthermore, the sign “IL” refers to inorganic ligands. The sign “AA” denotes alkanolamine.

In the method for producing the QD composition 20 according to this embodiment, as shown in FIG. 4 and FIG. 5, first, a QD composition 31 (a first QD composition) is prepared to contain: the QDs; the original ligands (OL), and a solvent 32 (a second organic solvent) that is a nonpolar organic solvent (Step S21). On the other hand, an inorganic ligand solution 33 is separately prepared to contain: the inorganic ligands (IL); and a solvent 34 (a third organic solvent) that is a polar organic solvent (Step S31). Next, the QD composition 31, the inorganic ligand solution 33, and alkanolamine (AA) are mixed together and stirred, such that ligand exchange is carried out (Step S22: a ligand exchange step). Thus, a QD composition 35 (a second QD composition) is obtained to contain the QD, the inorganic ligands (IL), the alkanolamine (AA), and the solvent 34.

Next, as shown in FIG. 4 and FIG. 6, the QD composition 35 obtained at the ligand exchange step (Step S22) is recovered (Step S23). Next, the recovered QD composition 35 is rinsed with a rinsing solution 36 (Step S24). Next, the rinsing solution 36 is removed. After that, the rinsed QDs, inorganic ligands (IL), and alkanolamine (AA) are precipitated into a poor solvent 37, centrifugally separated, and recovered as a precipitate 38 (Step S25). After that, the recovered precipitate 38 (specifically, the QDs, the inorganic ligands (IL), and the alkanolamine (AA)) is mixed with the solvent 21 (the first organic solvent) that is a polar organic solvent, stirred, and dispersed (Step S26: a mixing step).

Thus, the QD composition 20 is obtained to contain the QD, the inorganic ligands (IL), the alkanolamine (AA), and the solvent 21.

As described above, the QD composition 31 and the inorganic ligand solution 33 are prepared prior to the ligand exchange step (Step S22).

Note that, at Step S21, the QD composition 31 may be prepared of the QDs obtained by synthesis. To prepare the QD composition 31, the QDs, with which the original ligands are coordinated, are dispersed in the solvent 32 to have a desired concentration. Furthermore, the QD composition 31 may be a commercially available QD composition itself, or may be a commercially available QD composition prepared to have a desired concentration.

Moreover, at Step S31, the inorganic ligand material is measured and dissolved in the solvent 34 to have a desired concentration. Then, the inorganic ligand solution 33 is prepared to contain the inorganic ligands (IL) and the solvent 34.

At Step S22, the QD composition 31, the inorganic ligand solution 33, and the alkanolamine (AA) are mixed together and stirred. Hence, as illustrated at Step S22 in FIG. 5, a ligand exchange reaction from the original ligands (OL) to the inorganic ligands (IL) occurs, and the original ligands (OL) coordinated with the QD dispersed in the solvent 34 are substituted (exchanged) with the inorganic ligands (IL).

The ligand exchange reaction can be confirmed when a layer in which the fluorescence of the QDs can be confirmed transfers from a nonpolar organic solvent layer (a second organic solvent layer) containing the solvent 32 to a polar organic solvent layer (a third organic solvent layer) containing the solvent 34.

Here, A mol/L is a molarity of the original ligands (OL) dissolved in the solvent 32 of the QD composition 31. Furthermore, B mol/L is a molarity of the inorganic ligands (IL) in the inorganic ligand solution 33.

In the ligand exchange reaction, from a viewpoint of reaction rate, the inorganic ligands (IL) to be substituted with (the ligand exchange) are preferably found in an excess amount with respect to the original ligands (OL) to be substituted for. The more the amount of the inorganic ligands (IL) is than the amount of original ligands (OL), the faster the ligand exchange reaction is.

Hence, a molarity (A/B) of the inorganic ligands (IL) in the inorganic ligand solution 33 to a molarity of the original ligands (OL) dissolved (dispersed) in the solvent 32 is preferably B/A≥1. Furthermore, the B/A above is more preferably B/A≥10, and still more preferably B/A≥100.

Note that, as can be seen, the more the amount of the inorganic ligands (IL) is than the amount of original ligands (OL), the faster the ligand exchange reaction is. Hence, an upper limit value of B/A shall not be limited to a particular value. The upper limit value of B/A may be appropriately set from the viewpoints of, for example, solubility of the inorganic ligands (IL) in the solvent 34, production costs, an amount of the inorganic ligands (IL) contained in the QD composition 35 after a rinsing step, and protection of QDs in the QD composition 31.

For example, if B>1.0 M (mol/L) holds, the amount of the inorganic ligands (IL) contained in the QD composition 35 after the rinsing step (Step S24) is excessively large. As a result, the characteristics of the light-emitting element 1 could be adversely affected. Furthermore, if A<1.0×10⁻⁴ M (mol/L) holds, the amount of the original ligands in the QD composition 31 is excessively small such that the original ligands (OL) fail to sufficiently protect the QDs. As a result, the QDs could deteriorate. Hence, the B/A is desirably, for example, B/A≤10,000.

At Step S22, the organic ligands (OL) contained in the QD composition 31 and the inorganic ligands (IL) contained in the inorganic ligand solution 33 are mixed together to have the above relationship.

Furthermore, at Step S22, the alkanolamine (AA) is mixed so that a molar ratio of the alkanolamine (AA) to the inorganic ligands (IL) is within a range of 10 or more and 1000 or less. Hence, in a unit volume of the QD composition 20, the QD composition 20 can exhibit a molar ratio of the alkanolamine (AA) to the inorganic ligands in a range of 10 or more and 1000 or less the alkanolamine being included.

In this embodiment, as described above, the ligand exchange is carried out in the presence of the alkanolamine (AA). Because the ligand exchange is carried out in the presence of the alkanolamine (AA), the QD composition 20 with a high PLQY can be easily produced. In order to maintain the PLQY high, the amount of alkanolamine (AA) to be added has to be adjusted appropriately. Hence, the amount of the alkanolamine (AA) to be added is desirably set within the above range.

Moreover, a reaction temperature (a stirring temperature) in the ligand exchange reaction is not limited to a particular temperature. For example, in all Examples to be described later, the ligand exchanges are carried out in an environment at a normal temperature (approximately 25° C.). However, the higher the reaction temperature is, the faster the ligand exchange reaction is. Hence, at Step S22, in view of facilitating substitution (a reaction time and a reaction rate) with the inorganic ligands (IL), a liquid mixture of the QD composition 31, the inorganic ligand solution 33, and alkanolamine (AA) may be heated and stirred.

However, excessive heating may cause degradation of the QDs, although depending on the QD species. Hence, the reaction temperature (the stirring temperature) is desirably, for example, approximately 20° C. or higher and lower than 100° C.

Furthermore, the reaction time (a stirring time) of the ligand exchange reaction may be appropriately set so that the ligand exchange reaction concludes. The reaction time shall not be limited to a particular time. Although depending on, for example, the concentration of the inorganic ligands (IL), stirring the liquid mixture for approximately 30 minutes might not be sufficient for the ligand exchange. Hence, the liquid mixture is desirably stirred for at least one hour.

As described above, the solvent 32 to be used for the ligand exchange reaction is a nonpolar organic solvent, and the solvent 34 is a polar organic solvent. Hence, at Step S22, as S22 in FIG. 5 shows, the solvent 32 and the solvent 34 are phase-separated.

As an example, as will be described later in Example 1, FIG. 5 illustrates a case where the QDs are CdSe-based red QDs, the solvent 32 is octane, the inorganic ligand material is (NH₄)₂S, and the solvent 34 is DMSO. In this case, the upper layer is a nonpolar organic solvent layer (the second organic solvent layer) containing a nonpolar organic solvent (the solvent 32), and the lower layer is a polar organic solvent layer (the third organic solvent layer) containing a polar organic solvent (the solvent 34).

The polar organic solvent layer (the third organic solvent layer) after the ligand exchange is a QD composition layer (a second QD composition layer) made of the QD composition 35 (the second QD composition) containing: the QDs; the inorganic ligands (IL) coordinated with the QDs by the ligand exchange; the alkanolamine (AA); and the nonpolar organic solvent (the third organic solvent layer). Whereas, the nonpolar organic solvent layer (the second organic solvent layer) after the ligand exchange contains: the organic ligands (OL) after the ligand exchange; and the nonpolar organic solvent (the second organic solvent).

Hence, in this case, the upper layer is removed (separated) at Step S23, so that the QD composition 35 containing the QDs, the inorganic ligands (IL), the solvent 34, and the alkanolamine (AA) can be recovered.

At Step S23, as S23 shows in FIG. 6, for example, the upper layer is removed (separated), and the QD composition 35 of the lower layer is recovered in another reaction vessel. Note that the technique to recover the QD composition 35 in the lower layer alone may be any given technique including various known techniques.

At Step S24, for example, a nonpolar organic solvent serving as the rinsing solution 36 is added to the recovered QD composition 35. After that, the QD composition 35 is centrifugally separated from the rinsing solution 36. The separated QD composition 35 is recovered in another reaction vessel. At Step S24, for example, a series of the above operations is carried out as one set, and the set is repeated multiple times. Hence, the QD composition 35 is rinsed. Note that, also in this case, the QD composition 35 contains a polar organic solvent as the solvent 34, and a nonpolar organic solvent is used as the rinsing solution 36. Hence, by phase separation, the rinsed QD composition 35 can be recovered. Such a feature makes it possible to remove the original ligands (OL) contained in the QD composition 35 and not coordinated with the QDs.

At Step S25, as S24 shows in FIG. 6, a polar organic solvent, which dissolves less QDs than the solvent 34, is added as the poor solvent 37 to the rinsed QD composition 35 (i.e., the QD composition 35 recovered in the final set). The QD composition 35 undergoes centrifugal separation. Hence, the QDs, the inorganic ligands (IL), and the alkanolamine (AA) are precipitated as the precipitate 38. After that, the supernatant fluid containing the solvent 34 and the poor solvent 37 is removed, and the precipitate 38 is recovered. The precipitate 38 is a QD composition (a third QD composition) containing the QDs, the inorganic ligands (IL), and the alkanolamine (AA).

At Step S26, as S25 shows in FIG. 6, the solvent 21 is added to the recovered precipitate 38. The precipitate 38, which contains the QDs, the inorganic ligands (IL), and the alkanolamine (AA), is re-dispersed and adjusted to have an appropriate concentration.

Note that, as the solvent 32, a nonpolar organic solvent is used so that the QDs, with which the original ligands (OL) are coordinated, can be dispersed (dissolved) in the solvent. Furthermore, as the rinsing solution 36, a nonpolar organic solvent is used, so that, in the solvent, the ODs with which the inorganic ligands (IL) are coordinated are not dispersed (dissolved), and the original ligands (OL) contained in the QD composition 35 and not coordinated with the QDs can be dispersed (dissolved).

The nonpolar organic solvent to be used for the solvent 32 and the rinsing solution 36 is at least one organic solvent selected from the group consisting of nonpolar organic solvents having a relative permittivity (εᵣ value) of 1.84 or more and 6.02 or less measured approximately at 20° C. to 25° C.

Examples of such a nonpolar organic solvent include: pentane (εᵣ=1.84); hexane (εᵣ=1.89); heptane (εᵣ=1.92); octane (εᵣ=1.948); carbon tetrachloride (εᵣ=2.24); p-xylene (εᵣ=2.27); benzene (εᵣ=2.28); toluene (εᵣ=2.38); diethyl ether (εᵣ=4.34); chloroform (εᵣ=4.9); and ethyl acetate (εᵣ=6.02).

Furthermore, as the polar organic solvent to be used for the solvent 34, a nonpolar organic solvent is used, so that, in the solvent, the inorganic ligands (IL) can be dispersed (dissolved) as described before. The polar organic solvent is similar to the solvent 21, and preferably at least one organic solvent selected from the group consisting of polar organic solvents having a relative permittivity (Fr value) of 24.6 or more and 111.0 or less measured approximately at 20° C. to 25° C.

### EXAMPLES

Next, described with reference to Examples and Comparative Examples will be advantageous effects of the light-emitting element 1 according to this embodiment. Note that the light-emitting element 1 according to this embodiment is not limited to the light-emitting elements 1 in Examples.

### Example 1

First, 2.50×10⁻⁵ mol of (NH₄)₂S as an inorganic ligand material and 2 mL of DMSO as a polar organic solvent (the third organic solvent) were introduced into a reaction vessel, and the inorganic ligand material was dissolved in the DMSO. Thus, an inorganic ligand solution was prepared to contain S²⁻ as inorganic ligands. Next, to this inorganic ligand solution, 8.27×10⁻³ mol of ethanolamine was added as alkanolamine. In other words, to the above inorganic ligand solution, ethanolamine having 331 times the molar ratio of S²⁻ was added.

Next, a QD composition, having a concentration of 1 mg/mL, was introduced into the reaction vessel as a first QD composition. The first QD composition contained: CdSe-based red QDs with which original ligands (original ligands) were coordinated; and octane in which the CdSe-based red QDs were dissolved (dispersed). The octane served as a nonpolar organic solvent (the second organic solvent). Here, a molarity (B) of S²⁻ in the inorganic ligand solution is approximately 1.0×10⁻² M (mol/L). A molarity (A) of the original ligands dissolved (dispersed) in the octane of the first QD composition is approximately 1.0×10⁻³ M (mol/L). In this Example, the first QD composition was added so that B/A≈10 held.

Next, the solution in the reaction vessel was stirred with a stirrer for approximately two hours in a thermoneutral environment (at approximately 25° C.). Thus, ligand exchange was carried out.

As described with reference to FIG. 5, when the QDs are CdSe-based red QDs, the nonpolar organic solvent is octane, the inorganic ligand material is (NH₄)₂S, and the polar organic solvent is DMSO, the lower layer is a polar organic solvent layer. The polar organic solvent layer after the ligand exchange is a QD composition (the second QD composition) containing: the QDs; S²⁻ coordinated with the QDs; the ethanolamine; and the DMSO. On the other hand, the upper layer is a nonpolar organic solvent layer. The nonpolar solvent layer after the ligand exchange contains the original ligands and the octane.

Then, next, the upper layer was removed, and the QD composition in the lower layer was collected in a centrifuge tube. Next, the recovered QD composition (the second QD composition) was rinsed with hexane serving as a rinsing solution. Specifically, hexane was added to the recovered QD composition, the QD composition was centrifugally separated, and the QD composition in the lower layer was recovered in another centrifuge tube. This sequence of operations was counted one set, and the sequence was carried out twice (i.e., two sets) in total.

Next, to the recovered QD composition, acetonitrile serving as a poor solvent was added. The QD composition was centrifugally separated and the supernatant fluid was removed, so that a precipitate containing the QDs, the S²⁻, and the ethanolamine was recovered. Next, to the precipitate, DMSO serving as a polar organic solvent (the first organic solvent) was added. Thus, the QD composition according to this Example and containing: the QDs; the S²⁻ coordinated with the QDs; the ethanolamine; and the DMSO was produced as an EML material.

A PLQY of the EML material (the QD composition) was measured, using a quantum yield measuring apparatus. Note that, as the quantum yield measuring apparatus, a model “QE-1100” produced by Otsuka Electronics Co., Ltd. was used. As a result, the PLQY of the EML material (the QD composition) was 52%.

Meanwhile, on a glass substrate, an ITO film having a thickness of 30 nm was formed by sputtering to serve as an anode. Next, the anode was spin coated with a solution containing PEDOT:PSS. After that, the solvent in the solution was baked off and vaporized. Thus, a PEDOT:PSS film having a thickness of 40 nm was formed to serve as an HIL. Next, the PEDOT:PSS film was spin coated with a solution containing poly-TPD. After that, the solvent in the solution was baked off and vaporized. Thus, a poly-TPD film having a thickness of 40 nm was formed to serve as an HTL. After that, the surface of the poly-TPD film was treated with UV-O₃.

Next, the poly-TPD film was spin coated with the EML material (i.e., the QD composition containing: the QDs; the S²⁻ coordinated with the QDs, the ethanolamine, and the DMSO). Then, the DMSO in the EML material was baked off and evaporated. Hence, a QD-containing film having a thickness of 20 nm was formed to serve as an EML. The QD-containing film contains: the QDs; the S²⁻ coordinated with the QDs; and the ethanolamine.

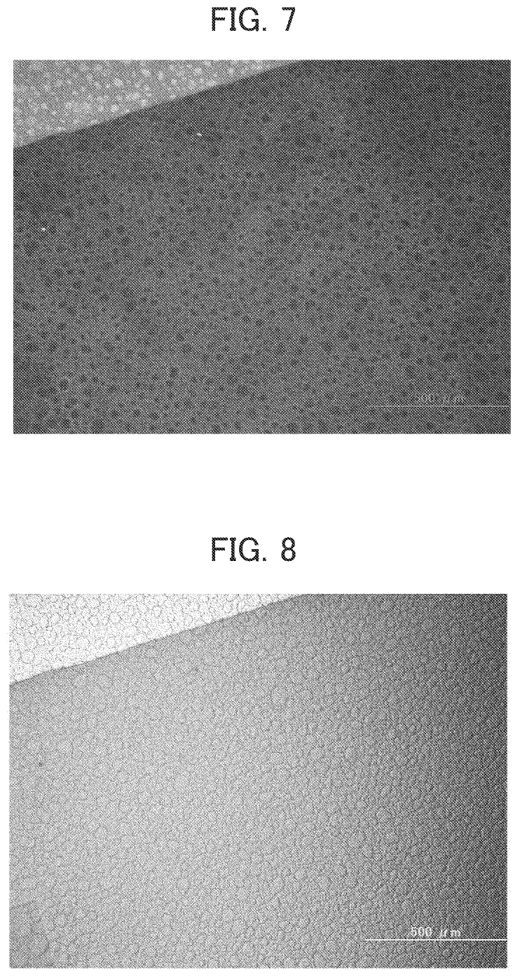

Then, a surface of the EML (the QD-containing film) was observed with a PL microscope (a polarization microscope) and a Nomarski differential interference contrast microscope. FIG. 7 is a PL photomicrograph of a surface of the EML (the QD-containing film) formed in this Example. Furthermore, FIG. 8 is a Nomarski differential interference contrast photomicrograph of the surface of the EML (the QD-containing film) formed in this Example.

Next, the EML (the QD-containing film) was spin coated with a solution containing ZnO nanoparticles. After that, the solvent in the solution was baked off and vaporized. Thus, a ZnO nanoparticle film having a thickness of 50 nm was formed to serve as an ETL. Next, on the ZnO nanoparticle film, an Al film having a thickness of 100 nm was formed by vacuum evaporation to serve as a cathode. Next, in a N₂ atmosphere, the glass substrate and the multilayer stack formed on the glass substrate were sealed with a sealing member. Thus, the light-emitting element according to this Example was obtained.

Furthermore, a voltage was applied to the light-emitting element to produce a current having a current density of 0 to 200 mA/cm². Then, with the application of the voltage, the light-emitting element emitted light. A luminance value of the emitted light was measured using an LED measuring apparatus (a spectrometer). Note that, as the LED (light-emitting diode) measuring apparatus, an LED measuring device of Spectra Co-op (a two-dimensional CCD small high-sensitivity spectrometer: “SolidLambda CCD” produced by Carl Zeiss) was used. After that, on the basis of the measured luminance value, an external quantum efficiency (EQE) of the light-emitting element was calculated.

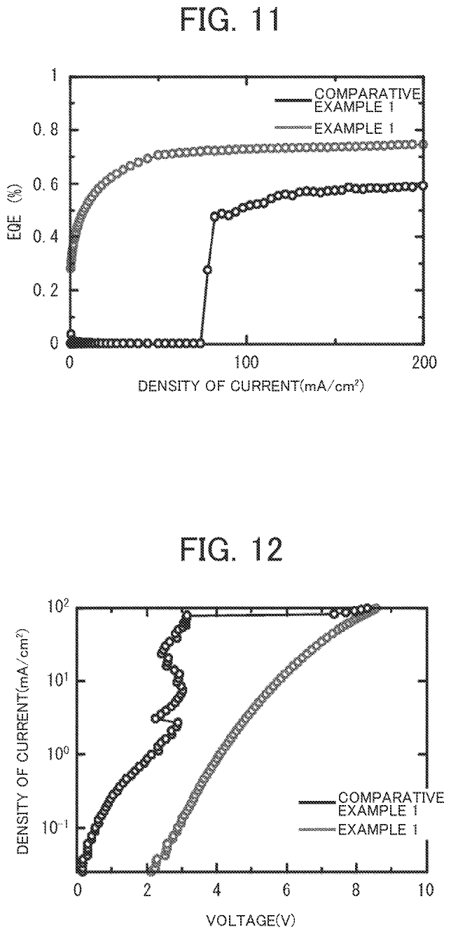

FIG. 11 shows an EQE of the light-emitting element with respect to a current density. Furthermore, FIG. 12 shows a density of the current flowing with respect to the voltage applied to the light-emitting element. As shown in FIG. 11, the light-emitting element obtained in this Example had a maximum EQE value (an EQE max) of 0.75%.

### Comparative Example 1

In Example 1, no alkanolamine was added. Otherwise, the same procedure as the procedure in Example 1 was carried out, and a QD composition according to this Comparative Example was produced to serve as an EML material. In addition, as an EML material, the EML material obtained in this Comparative Example was used. Otherwise, the same procedure as the procedure in Example 1 was carried out, and a light-emitting element according to this Comparative Example was produced.

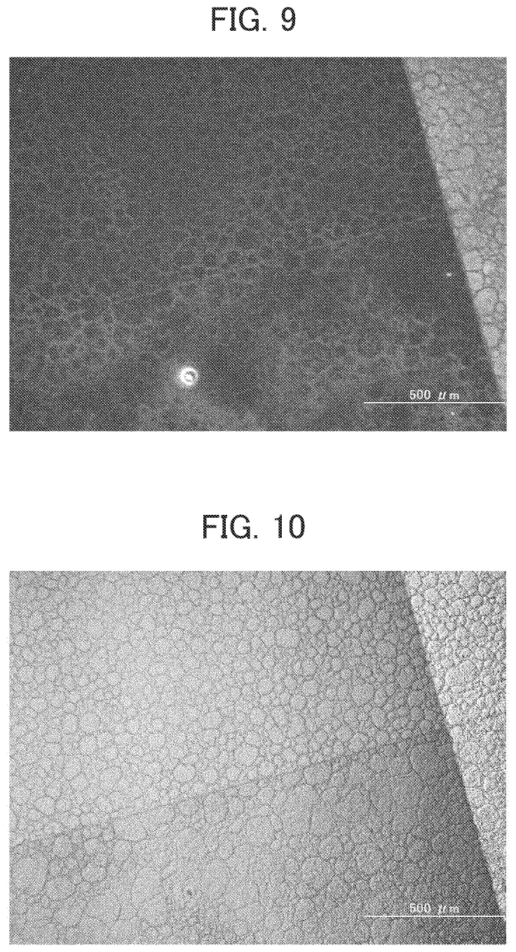

FIG. 9 is a PL photomicrograph of a surface of the EML (a QD-containing film) formed in this Comparative Example. Furthermore, FIG. 10 is a Nomarski differential interference contrast photomicrograph of the surface of the EML (the QD-containing film) formed in this Comparative Example.

FIGS. 7 to 10 show that, the additional alkanolamine in Example 1 makes it possible to form a QD-containing film with less unevenness than the QD-containing film of Comparative Example 1.

The PLQY of the EML material (the QD composition) obtained in this Comparative Example was measured by the same technique as the technique of Example 1. The resulting PLQY was 36%.

Furthermore, the EQE of the light-emitting element obtained in this Comparative Example was calculated by the same technique as the technique of Example 1.

FIG. 11 shows an EQE of the light-emitting element with respect to a current density, together with an EQE, of the light-emitting element obtained in Example 1, with respect to a current density. Furthermore, FIG. 12 shows a density of a current flowing with respect to a voltage applied to the light-emitting element, together with a density of a current flowing with respect to a voltage applied to the light-emitting element obtained in Example 1. As shown in FIG. 11, the light-emitting element obtained in this Comparative Example had a maximum EQE value (an EQE max) of 0.60%.

Table 1 collectively shows, as to Example 1 and Comparative Example 1, molar ratios of ethanolamine to S²⁻ (S²⁻/ethanolamine), PLQYs of QD compositions serving as EMLs after ligand exchange, and the EQE max of the light-emitting elements. Note that, in Table 1 the sign “EA” denotes ethanolamine.

TABLE 1

| | S²⁻/EA (Molar Ratio) | PLQY | EQE Max |
|---|---|---|---|
| Example 1 | 331 Times | 52% | 0.75% |
| Comparative | 0 Times | 36% | 0.60% |
| Example 1 | (EA Not Added) | | |

As FIG. 11, FIG. 12, and Table 1 show, the additional ethanolamine as alkanolamine in Example 1 makes it possible to form a QD-containing film that excels the QD-containing film of Comparative Example 1 at emission characteristics.

### Example 2

In Example 1, CdSe-based green QDs were used as the QDs, 2.50×10⁻⁵ mol of Na₂S·9H₂O was used as the inorganic ligand material, and the ethanolamine had 1000 times the molar ratio of S²⁻. Otherwise, the same procedure as the procedure in Example 1 was carried out, and a QD composition according to this Example was produced. A PLQY of the obtained QD composition was measured by the same technique as the technique of Example 1. The resulting PLQY was 66%.

### Example 3

In Example 2, the ethanolamine had 100 times the molar ratio of S²⁻. Otherwise, the same procedure as the procedure in Example 2 was carried out, and a QD composition according to this Example was produced. A PLQY of the obtained QD composition was measured by the same technique as the technique of Example 1. The resulting PLQY was 71%.

### Example 4

In Example 2, the ethanolamine had 10 times the molar ratio of S²⁻. Otherwise, the same procedure as the procedure in Example 2 was carried out, and a QD composition according to this Example was produced. A PLQY of the obtained QD composition was measured by the same technique as the technique of Example 1. The resulting PLQY was 59%.

### Comparative Example 2

In Example 2, the ethanolamine had 2500 times the molar ratio of S²⁻. Otherwise, the same procedure as the procedure in Example 2 was carried out, and a QD composition according to this Comparative Example was produced. A PLQY of the obtained QD composition was measured by the same technique as the technique of Example 1. The resulting PLQY was 47%.

### Comparative Example 3

In Example 2, the ethanolamine had 1 time the molar ratio of S²⁻. Otherwise, the same procedure as the procedure in Example 2 was carried out, and a QD composition according to this Comparative Example was produced. A PLQY of the obtained QD composition was measured by the same technique as the technique of Example 1. The resulting PLQY was 29%.

### Comparative Example 4

In Example 2, no alkanolamine was added. Otherwise, the same procedure as the procedure in Example 2 was carried out, and a QD composition according to this Comparative Example was produced. A PLQY of the obtained QD composition was measured by the same technique as the technique of Example 1. The resulting PLQY was 26%.

### Example 5

In Example 3, DMF was used instead of DMSO to serve as the polar organic solvent serving as the third organic solvent and the first organic solvent. Otherwise, the same procedure as the procedure in Example 3 was carried out, and a QD composition according to this Example was produced. A PLQY of the obtained QD composition was measured by the same technique as the technique of Example 1. The resulting PLQY was 66%.

### Comparative Example 5

In Example 5, no alkanolamine was added. Otherwise, the same procedure as the procedure in Example 5 was carried out, and a QD composition according to this Comparative Example was produced. Note that this Comparative Example may also be interpreted that, in Comparative Example 4, DMF was used instead of DMSO to serve as the polar organic solvent serving as the third organic solvent and the first organic solvent. Otherwise, the same procedure as the procedure in Comparative Example 4 was carried out, and a QD composition according to this Comparative Example was produced. A PLQY of the obtained QD composition was measured by the same technique as the technique of Example 1. The resulting PLQY was 43%.

### Example 6

In Example 3, butanolamine was used in stead of ethanolamine to serve as alkanolamine. Otherwise, the same procedure as the procedure in Example 3 was carried out, and a QD composition according to this Example was produced. A PLQY of the obtained QD composition was measured by the same technique as the technique of Example 1. The resulting PLQY was 72%.

### Comparative Example 6

In Example 3, octylamine was used instead of alkanolamine. Otherwise, the same procedure as the procedure in Example 3 was carried out. No ligand exchange was carried out from the original ligands (organic ligands) to the inorganic ligands.

### Comparative Example 7

In Example 3, dodecanethiol was used instead of alkanolamine. Otherwise, the same procedure as the procedure in Example 3 was carried out. No ligand exchange was carried out from the original ligands (organic ligands) to the inorganic ligands.

Table 2 collectively shows the QDs used in Examples 1 to 6 and Comparative Examples 1 to 7, surfactants, molar ratios of alkanolamine to S²⁻, polar organic solvents as the third organic solvent and the first organic solvent, and PLQYs of QD compositions. Note that, in Table 2, the sign “AA” denotes alkanolamine.

TABLE 2

| | | | S²⁻/AA | | Polar Organic | |
|---|---|---|---|---|---|---|
| | QD | Surfactant | (Molar Ratio) | | Solvent | PLQY |
| Example 1 | CdSe-Based Red QD | Ethanolamine | 331 | Times | DMSO | 52% |
| Comparative Example 1 | CdSe-Based Red QD | —(Not Added) | 0 | Times | DMSO | 36% |
| Example 2 | CdSe-Based Green QD | Ethanolamine | 1000 | Times | DMSO | 66% |
| Example 3 | CdSe-Based Green QD | Ethanolamine | 100 | Times | DMSO | 71% |
| Example 4 | CdSe-Based Green QD | Ethanolamine | 10 | Times | DMSO | 59% |
| Comparative Example 2 | CdSe-Based Green QD | Ethanolamine | 2500 | Times | DMSO | 47% |
| Comparative Example 3 | CdSe-Based Green QD | Ethanolamine | 1 | Time | DMSO | 29% |
| Comparative Example 4 | CdSe-Based Green QD | —(Not Added) | 0 | Times | DMSO | 26% |
| Example 5 | CdSe-Based Green QD | Ethanolamine | 100 | Times | DMF | 66% |
| Comparative Example 5 | CdSe-Based Green QD | —(Not Added) | 0 | Times | DMF | 43% |
| Example 6 | CdSe-Based Green QD | Butanolamine | 100 | Times | DMSO | 72% |
| Comparative Example 6 | CdSe-Based Green QD | Octylamine | 0 | Times | DMSO | — |
| Comparative Example 7 | CdSe-Based Green QD | Dodecanethiol | 0 | Times | DMSO | — |

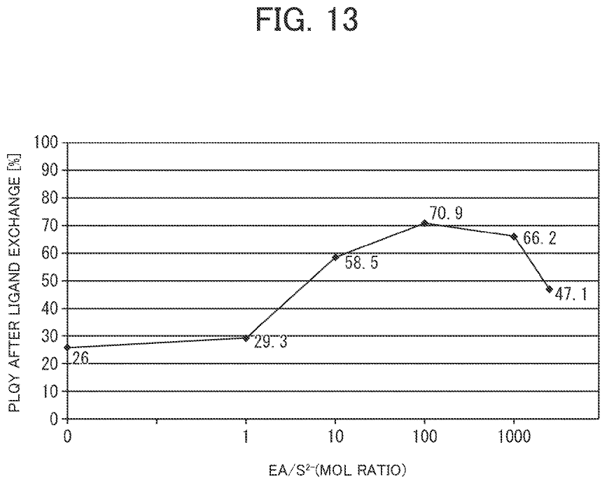

As shown in Table 2, there is a preferable range for the amount of alkanolamine to be added. FIG. 13 is a graph showing a relationship between: a molar ratio of ethanolamine to S²⁻ in the light-emitting element obtained in each of Examples 2 to 4 and Comparative Examples 2 to 4; and a PLQY of a quantum dot composition after ligand exchange in each of Examples 2 to 4 and Comparative Examples 2 to 4. As can be seen from Table 2 and FIG. 13, in this embodiment, the molar ratio of alkanolamine to inorganic ligands is preferably in a range of 10 or more and 1000 or less. Thus, the QD composition can have a PLQY of more than 50% in a state of solution.

Furthermore, as can be seen from Example 5 and Comparative Example 5 in Table 2, additionally introduced alkanolamine can improve the PLQY of the QD composition even if a different solvent (other than DMSO) is used as a high polar organic solvent.

Moreover, as can be seen from Example 3 and Example 6 in Table 2, similar advantageous effects can be obtained even if a length of a main chain of alkanolamine is changed from, for example, 2 to 4.

In addition, unlike alkanolamine, QDs with which a surfactant having no hydroxy group (—OH group) is coordinated are nonpolar QDs. Because QDs are dispersed not in a polar organic solvent but in a nonpolar organic solvent, use of a surfactant having no hydroxy group as seen in Comparative Examples 6 and 7 results in inhibition of substitution reaction with inorganic ligands.

Note that, when the CdSe-based green QDs, with which the original ligands were coordinated, were dissolved (dispersed) in octane, the PLQY of the QD composition was 89%. Here, the QD composition was used in Examples 2 to 6 and Comparative Examples 2 to 7, and had a concentration of 1 mg/mL. Hence, the above results show that when the ligand exchange is carried out in this embodiment, an appropriate amount of alkanolamine is added together with an inorganic ligand material, such that the ligand exchange with the inorganic ligands can be carried out while the PLQY of the QD composition is maintained.

Note that the external quantum efficiency (EQE) is represented by, for example, Equation (1) as follows:

$$External Quantum Yield ( EQE ) = Carrier Balance \times Photoluminescence Quantum Yield ( PLQY ) \times Light Releasing Efficiency . \qquad ( 1 )$$

Thus, a higher EQE can be obtained with a higher PLQY For example, as shown in Table 1, the obtained PLQY can be higher when an appropriate amount of alkanolamine is added together with the inorganic ligand material than when no alkanolamine is used. As a result, a high EQE can be obtained.

As described above, this embodiment can provide the light-emitting element 1 including QDs with which inorganic ligands are coordinated as ligands, such that the light-emitting element 1 develops little unevenness, exhibits excellent emission characteristics, and achieves high efficiency. Furthermore, this embodiment can provide a quantum dot composition and a method for producing the quantum dot composition, and a method for producing a quantum-dot-containing film to be suitably used for producing the quantum-dot-containing film that develops little unevenness and exhibits excellent emission characteristics, and the quantum-dot-containing film. As a result, this embodiment can provide the light-emitting element 1 as described above.

### Modifications

Patent Document 1 exemplifies a case where the QD-containing film according to the present disclosure is the EML of the light-emitting element 1. However, the QD-containing film according to the present disclosure may be, for example, a wavelength converting layer in a wavelength converting member, or a QD-containing film in a photoelectric conversion element such as a solar cell. The QD composition according to the present disclosure is used for depositing a QD-containing film serving as a wavelength converting layer. Such a feature can provide a wavelength converting member that develops little unevenness and exhibits excellent light emission characteristics. Furthermore, the QD composition according to the present disclosure is used for depositing a QD-containing film for a solar cell. Such a feature can provide a solar cell that develops little unevenness, causes few exciton deactivations in the QDs, and achieves high photoelectric conversion efficiency.

The present disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the present disclosure. Moreover, the technical aspects disclosed in each embodiment may be combined together to achieve a new technical feature.

### REFERENCE SIGNS LIST

1 Light-Emitting Element
12 Anode (First Electrode)
15 EML (Quantum-Dot-Containing Film, Light-Emitting Layer)
17 Cathode (Second Electrode)
20 QD Composition
21 Solvent (First Organic Solvent)
31 QD Composition (First Quantum Dot Composition)
35 QD Composition (Second Quantum Dot Composition)
32 Solvent (Second Organic Solvent)
33 Inorganic Ligand Solution
34 Solvent (Third Organic Solvent)
38 Precipitate (Third Quantum Dot Composition)
QD Quantum Dots
IL Inorganic Ligand
OL Organic Ligand
AA Alkanolamine

1. A quantum-dot-containing film, comprising:
quantum dots; inorganic ligands; and alkanolamine,
wherein, in a unit volume of the quantum-dot-containing film, a molar ratio of the alkanolamine to the inorganic ligands is in a range of 10 or more and 1000 or less.

2. The quantum-dot-containing film according to claim 1,
wherein the alkanolamine contains an alkane skeleton having 1 to 5 carbon atoms.

3. The quantum-dot-containing film according to claim 1,
wherein the inorganic ligands contain at least one kind of inorganic ligands selected from a group consisting of monoatomic anions or polyatomic anions containing a group 16 element.

4. The quantum-dot-containing film according to claim 1,
wherein the inorganic ligands contain at least one selected from a group consisting of S²⁻, Se²⁻, and Te²⁻.

5. The quantum-dot-containing film according to claim 1,
wherein the inorganic ligands contain S²⁻.

6. A light-emitting element, comprising:
a first electrode; a second electrode; and a light-emitting layer provided between the first electrode and the second electrode,
wherein the light-emitting layer is the quantum-dot-containing film according to claim 1.

7. A quantum dot composition, comprising:
quantum dots; inorganic ligands; alkanolamine; and a first organic solvent,
wherein, in a unit volume of the quantum dot composition, a molar ratio of the alkanolamine to the inorganic ligands is in a range of 10 or more and 1000 or less.

8. The quantum dot composition according to claim 7,
wherein the inorganic ligands contain at least one kind of inorganic ligands selected from a group consisting of monoatomic anions or polyatomic anions containing a group 16 element.

9. The quantum dot composition according to claim 7,
wherein the inorganic ligands contain at least one selected from a group consisting of S²⁻, Se²⁻, and Te²⁻.

10. The quantum dot composition according to claim 7,
wherein the inorganic ligands contain S²⁻.

11. The quantum dot composition according to claim 7,
wherein the alkanolamine contains an alkane skeleton having 1 to 5 carbon atoms.

12. The quantum dot composition according to claim 7,
wherein the first organic solvent is a polar organic solvent having a relative permittivity of 24.6 or more and 111.0 or less.

13. A method for producing the quantum dot composition according to claim 7, the method comprising:
a ligand exchange step of carrying out ligand exchange by mixing together (i) a first quantum dot composition containing the quantum dots, organic ligands, and a second organic solvent, (ii) an inorganic ligand solution containing the inorganic ligands and a third organic solvent, and (iii) the alkanolamine; and
a mixing step of (i) recovering a second quantum dot composition obtained at the ligand exchange step and containing the quantum dots, the inorganic ligands, the third organic solvent, and the alkanolamine, (ii) rinsing the second quantum dot composition with a rinsing solution, (iii) recovering a third quantum dot composition containing the quantum dots, the inorganic ligands, and the alkanolamine, and (iv) mixing the third quantum dot composition with the first organic solvent.

14. The method for producing the quantum dot composition according to claim 13,
wherein each of the second organic solvent and the rinsing solution is a nonpolar organic solvent having a relative permittivity of 1.84 or more and 6.02 or less, and
each of the third organic solvent and the first organic solvent is a polar organic solvent having a relative permittivity of 24.6 or more and 111.0 or less.

15. The method for producing the quantum dot composition according to claim 13,
wherein the ligand exchange step involves stirring a mixture of the first quantum dot composition, the inorganic ligand solution, and the alkanolamine at a temperature of 20° C. or higher and lower than 100° C.

16. The method for producing the quantum dot composition according to claim 13,
wherein, as to the first quantum dot composition, where A mol/L is a molarity of the organic ligands dissolved in the second organic solvent, and B mol/L is a molarity of the inorganic ligands in the inorganic ligand solution, B/A≥1 holds.

17. A method for producing a quantum-dot-containing film deposited by coating with the quantum dot composition according to claim 7.
